(19) United States
(12) Patent Application Publication
(10) Pub. No.: US 2019/0196907 A1
(43) Pub. Date: Jun. 27, 2019

(54) COMPRESSION TECHNIQUES FOR DISTRIBUTED DATA

(71) Applicant: Intel Corporation, Santa Clara, CA (US)

(72) Inventors: Jawad B. KHAN, Portland, OR (US); Sanjeev N. TRIKA, Portland, OR (US)

(21) Appl. No.: 16/293,540

(22) Filed: Mar. 5, 2019

(51) Int. Cl. G06F 11/10; H03M 13/15; G06F 3/06

(52) U.S. Cl. CPC G06F 11/1076; H03M 13/154; G06F 3/0644; G06F 3/0619; G06F 3/0683

(57) ABSTRACT

In one example, uncompressed data is compressed and divided into chunks. Each chunk of the compressed data stream is combined with state information to enable each chunk to be independently decompressed. Each of the compressed chunks is then stored on a different storage device along with its associated state information. A compute operation can then be offloaded to the device or node where each chunk is stored. Each chunk can be independently decompressed for execution of the offloaded operation without transferring all chunks to a central location for decompression and performance of the operation.

### FIELD

The descriptions are generally related to computers and more specifically to data compression and compute offloads.

### BACKGROUND

Data compression enables data to be compressed to reduce the size of data that is stored and transferred.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” or “examples” are to be understood as describing a particular feature, structure, and/or characteristic included in at least one implementation of the invention. Thus, phrases such as “in one embodiment” or “in one example” appearing herein describe various embodiments and implementations of the invention, and do not necessarily all refer to the same embodiment. However, they are also not necessarily mutually exclusive.

FIG. 1A illustrates an example of a compression technique.

FIG. 1B illustrates an example of erasure coding the compressed data of FIG. 1A.

FIG. 2A illustrates an example of pseudocode for producing parity data.

FIG. 2B illustrates an example of pseudocode for offloading an operation on compressed and distributed data by a master controller.

FIG. 2C illustrates an example of pseudocode for performing the offload at a storage node.

FIG. 3 illustrates an example of offloading operations on the compressed data.

FIG. 4 is a flow chart illustrating an example of a method of compressing and storing data.

FIG. 5 is flow chart of an example of a method of handling an offload request on compressed data.

FIG. 6 illustrates an example of a disaggregated rack architecture in which compression and offload techniques may be implemented.

FIG. 7 provides an exemplary depiction of a computing system in which compression and offloading techniques can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

The present disclosure describes techniques for compression that can enable individually decompressing a chunk of compressed data at the device or node where it resides to enable local offload operations.

Bringing select compute operations close to storage devices can provide significant performance, power, and scalability advantages. However, when the data is compressed as well as distributed, the offload operations cannot run because the compressed data on any given node typically may not be decompressed without knowledge of the data on other nodes. For example, if a file is compressed and then split across five nodes, then a search operation cannot be delegated to the five nodes, since the split portions cannot be independently decompressed.

In contrast, the techniques described in this disclosure enable individually decompressing each EC (erasure coding) code while retaining the benefits of encoding a large file. In one example, compressed data is divided into chunks such that no tokens span multiple chunks. Each chunk is combined with state information to enable independent decompression. The combined chunks and associated state information can be erasure coded to generate parity information. Subsequent operations on the compressed data can be offloaded to where each chunk is stored to enable parallel decompression and offloading.

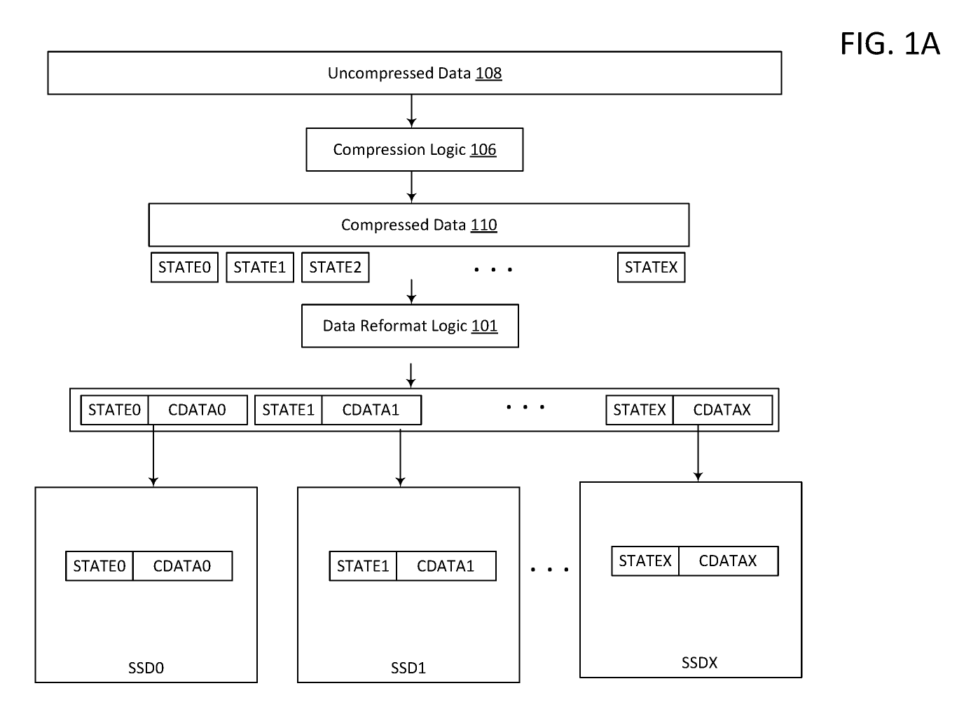

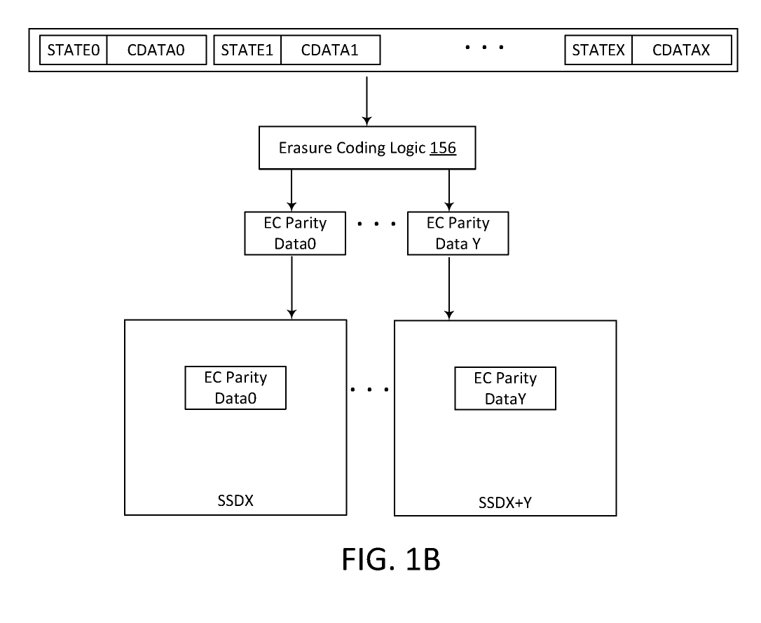

FIG. 1A illustrates an example of a compression technique. An uncompressed data stream 108 is fed to compression logic 106. The compression logic 106 can be software, hardware, or a combination. The compression logic 106 compresses the incoming data 108 and outputs compressed data 110. The compression logic 106 can include a codec (coder-decoder) that encodes and compresses the incoming uncompressed data and decompresses coded compressed data. The compression logic 106 compresses the data using a compression algorithm.

A variety of compression algorithms can be used, some of which are more suitable for certain types of data. Some compression algorithms are “lossless.” Lossless compression algorithms compress the data to ensure recovery of the uncompressed data without any loss of information. Examples of lossless compression algorithms include Lempel-Ziv (LZ), Lempel-Ziv-Welch (LZW), prediction by partial matching (PPM), Huffman coding, Run-length encoding (RLE), Portable Network Graphics (PNG), Tagged Image File Format (TIFF), and grammar or dictionary-based algorithms. Other compression algorithms are “lossy.” Lossy compression algorithms compress data by discarding information that is determined to be nonessential. Thus, lossy compression is typically irreversible (i.e., data compressed with a lossy compression algorithm typically cannot be decompressed to its original form). Lossy compression algorithms are typically used for multimedia files (e.g., images, streaming video, audio files, or other media data). Lossless compression is typically used for files that need to be reconstructed without any loss of information. For example, it is typically undesirable to drop information from text files (e.g., emails, records, or other documents containing text) or program files (e.g., executable files or other program data files); therefore, such files are typically compressed with a lossless compression algorithm. Compression techniques involve storing information (e.g., codec state information) to enable decompression of the compressed data. The codec state information can include, for example, information identifying the type of compression algorithm, a model, a dictionary, and/or other information to enable decompression of the data.

Referring again to FIG. 1A, the compression logic divides the compressed data into multiple chunks or portions. The compression logic produces state information associated with each chunk of the compressed data. In one example, a data reformat block 101 that receives the compressed data 110 along with the associated state information (State0-StateX) and combines the state information with the associated chunk. The data reformat block 101 can include software, hardware, firmware, or a combination. In the example illustrated in FIG. 1A, the data reformat block 101 prepends the state information to the associated chunk. The Compressed Data (CDATA) chunks are then written to storage devices (e.g., SSD0-SSDX) along with the state information. Each chunk of a given compressed data stream is stored in a different storage device its associated state information.

Referring now to FIG. 1B, the output of the data reformat block is fed into erasure coding logic 156, which produces erasure coding (EC) parity data (EC Parity Data 0-EC Parity Data Y). The EC parity data is then written to storage devices. In the illustrated example, the EC parity data is written to storage devices allocated for EC (e.g., SSDX-SSDX+Y), which are different than the storage devices storing the chunks and associated state information. Thus, this technique differs from conventional compression and erasure coding techniques in several ways. As mentioned above, traditional compression algorithms include dictionary state information only at the beginning of the compressed data stream. If the compressed data is then divided and stored across multiple storage devices, only the first chunk of the compressed data would have the state information and the chunks may include split tokens. Here, each chunk includes only a single token and each chunk is combined with state information to enable independent decompression. Furthermore, in conventional erasure coding techniques, the erasure coding would be performed on each chunk of the compressed data. Thus, a given chunk may be further split/and or encoded to include parity information. Here, in one example, the parity information is computed for all the chunks and associated state information together. Each chunk together with its associated state information is an EC-code. The computed parity information makes up the other EC-codes. In this way, the compression/decompression algorithm is erasure-coding aware in the sense that each chunk with its associated state information is an EC-code.

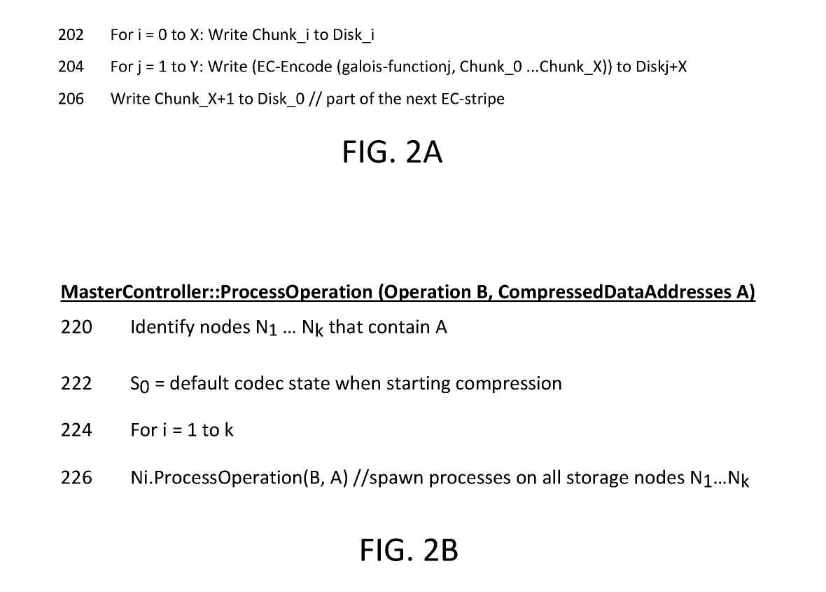

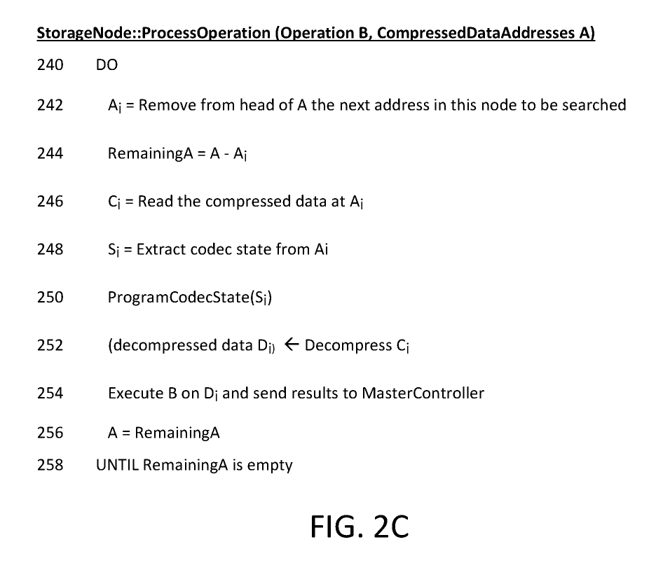

FIG. 2A illustrates an example of pseudocode for producing parity data. In the example illustrated in FIG. 2A, for i=0 to X (where the compressed data is split into X+1 chunks), chunk_i is written to disk_i, at line 202. In this example, “chunk_i” includes the compressed data chunk in addition to its associated state information. For j=1 to Y (where Y is a redundancy level that allows Y disks to fail without data loss), parity information is written to Diskj+X, where the parity information is given by an erasure coding function: EC-Encode (galois-functionj, Chunk_0 . . . chunk_X), at line 204. The last chunk, Chunk_X+1, is then written to Disk_0 as part of the next EC-stripe, at line 206.

Thus, each chunk of compressed data is stored with sufficient state information to enable independent decoding of the chunk and EC information for the chunks combined with the state information is stored separately to enable error correction.

FIGS. 2B and 2C are examples of pseudo code of a scheme that enables execution of operation on a compressed data stream that is split across multiple nodes with dictionary state for each node stored with the compressed chunk.

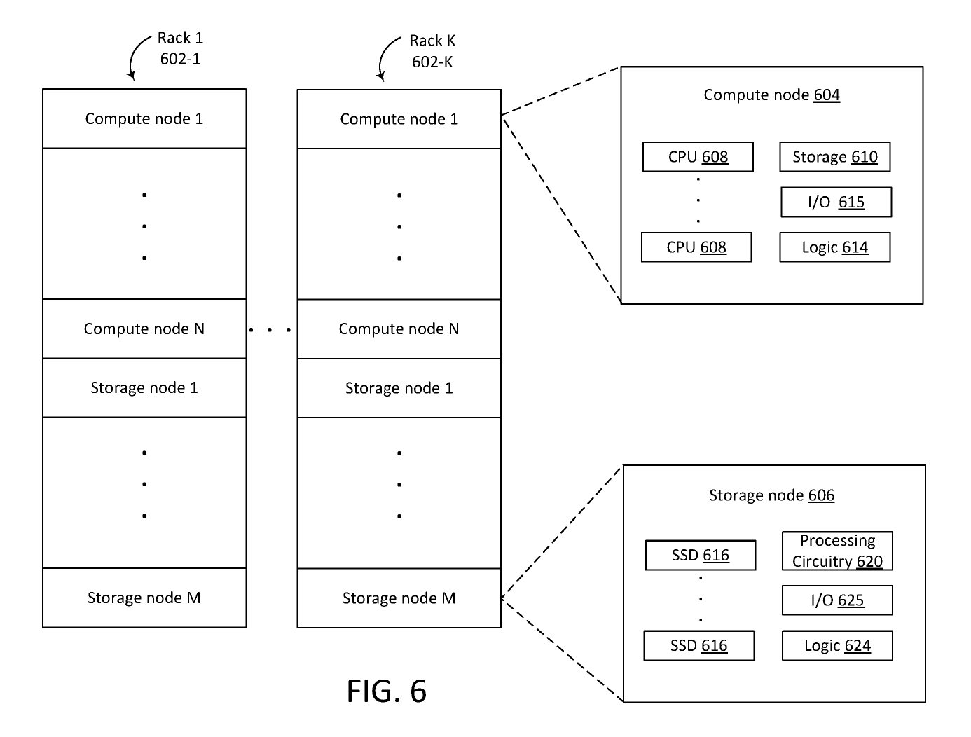

FIG. 2B illustrates an example of pseudocode for offloading an operation on compressed and distributed data by a master controller. The pseudocode of FIG. 2B illustrates a function called MasterController::ProcessOperation that can be performed, for example, by a compute node such as the compute node 604 of FIG. 6, discussed below. The MasterController::ProcessOperation function receives an operation B to perform (e.g., an offload-binary B) and the addresses A of the compressed data.

The pseudocode of the MasterController::ProcessOperation function starts at line 220 with identifying the nodes N₁-Nₖ that contain the data at addresses A. Determining which nodes store the data at addresses A varies depending on the implementation. In one example, determining the location of data involves either determining locations based on a map or algorithmically. In one example, the physical location of chunks of data is defined by a node number (e.g., sled number), disk number, and a sector range on that disk (e.g., logic block address (LBA) where the code is stored). In the illustrated example, the default codec state, S₀, is then initialized, at line 222. After the nodes storing the compressed data are identified, the request is sent to all the nodes (nodes 1-k), at lines 224-226. Because the chunks can be independently decompressed, the request can be sent concurrently to all nodes. The request includes the operation (B) to be performed and the address range A of the compressed data.

FIG. 2C illustrates an example of pseudocode for performing the offload at a storage node. The pseudocode of FIG. 2C illustrates a function called Storage Node::ProcessOperation that can be performed, for example, by a storage node that stores a compressed chunk, such as the storage node 606 of FIG. 6. The function StorageNode::ProcessOperation receives the offload-binary B, and the addresses A of the compressed data.

The pseudocode of the StorageNode::ProcessOperation function starts at lines 240-242 with removing the head of the addresses A and storing the head in Ai. Thus, Ai stores the head of the address storing the next compressed data on which to perform the operation B. The remaining addresses (A-Ai) are then stored in RemainingA, at line 244. The storage node reads the compressed data at the addresses Ai and stores the compressed data in Ci, at line 246. At line 248, the storage node then extracts the codec state from Ai and stores it in Si. At line 250, the codec state is programmed based on the extracted codec state. In this example, the codec state for each chunk is extracted from that chunk, making it unnecessary to receive codec state from other nodes. The storage node then decompresses the data Ci, at line 252. The output of the decompression is the decompressed data Di. The storage node then executes B on the decompressed data Di and sends results to the master controller, at line 254. The compressed data addresses A is then updated with the remaining addresses at line 256. The operations are then repeated until all the compressed data addresses have been processed (e.g., the RemainingA is empty), at line 258.

Consider an exemplary scenario in which the uncompressed data-stream data is 2 MB. Referring to FIG. 1A, the 2 MB of uncompressed data 108 is provided to the compression logic 106. In this example, the data is compressed with a 2× compression ratio using a dictionary-based compression technique. Thus, in this example, the uncompressed data is compressed to 1 MB of compressed data plus dictionary state information (DictStaten), which is 5 KB for each chunk of 95 kB of the 1 MB compressed data. The compressed data 108 is logically divided into eleven chunks, the first ten of which are 95 KB each (95=100 kB code word size−5 kB dictionary state size), and the eleventh chunk, which is 74 kB in this example (1024 kB size of compressed data minus 950 kB in the first ten chunks). This logical division is approximate, and in practice ensures that none of the compressed tokens span multiple chunks. Each chunk is then fed to the data reformat logic 101, which prepends each chunk CDATAN with STATEN.

The prepending operation results in ten chunks (including the state information) which are 100 kB and the eleventh chunk, which is 79 kB. The last chunk may then be padded with zeroes for simplicity, or the space may be used for the next data stream. Assuming in this example that there are 10 SSDs for storing the chunks (SSD0-SSD9), the last chunk (CDATA10) is written with its state information to disk 0 after the location where CDATA0 was written. The resulting eleven chunks (including the state information) of 100 kB each are saved with 10+4 redundancy (e.g., EC protection). Therefore, in this example the compressed data must be encoded across 14 disks, with a redundancy level that allows for 4 disks to fail without data loss. In this example, each chunk (CDATA0-CDATA9) is stored on a different storage device along with its associated state information. The parity information (EC Parity Data 0-EC Parity Data 3) is stored on storage devices other than where the compressed data chunks are stored. In this example, the EC code-word size is 100 kB. In this example, each chunk prepended with the state information is considered a code (even though it is not combined with parity information in this example) and the four “EC Parity Data” are the remaining 4 codes for a total of 14 codes. For example, if the first 10 codes (CDATA0-CDATA9 and associated state information) are stored on SSD0-SSD9, the remaining 4 codes (parity information) may be stored across SSD10-SSD13. The last chunk (CDATA10) can then be stored to SSD0 (or another SSD).

Although FIGS. 1A and 1B show separate blocks for the compression logic 106 and erasure coding logic 156, the compression logic and erasure coding logic can be integrated. In one example, the compression and the EC-engine are integrated and termed a CEC (compression plus EC engine). The CEC first compresses the data stream using one of the chosen compression algorithm. CEC then splits the compressed data streams into codes that provide EC-protection, and that also include the relevant portion of the compression dictionary for that code. CEC also ensures that compressed tokens are not split across codes. This scheme can ensure that the best global compression scheme/dictionary is used for the entire data range, and each code can be individually decompressed on its storage node for local offload operation. The downside is that portions of the dictionary are replicated across the codes, which slightly decreases the compression ratio.

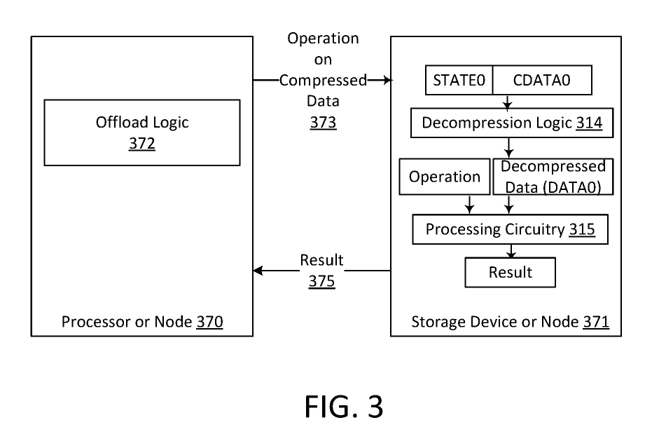

FIG. 3 illustrates an example of offloading operations on the compressed data. The example in FIG. 3 shows a processor or node 370 offloading an operation to a storage device or node 371. The processor 370 can be in a separate node or a same node as storage device 371. For example, in a disaggregated server architecture, a node with processor 370 may have primarily compute resources (e.g., a “compute node”) and the node 371 may have primarily storage resources (e.g., a “storage node”). In another example, the processor 370 is on a node with the same or similar resources as the node 371. In another example, the processor 370 and the storage device 371 are a part of the same physical computer.

Regardless of whether the processor and storage device 371 are a part of the same or different nodes, the processor 370 is running a process that needs to access compressed data that is stored across multiple storage devices. In conventional systems, the processor 370 would need to retrieve the compressed data from each storage device where it is stored prior to decompressing. After receiving every chunk of a compressed data stream, the processor could decompress the data and perform the operation. Therefore, in order to perform the operation on the compressed and distributed data, a significant amount of data is transferred between the processor and storage devices.

In contrast, the technique described herein enables offloading the operation to where the compressed data chunks are stored, which can significantly reduce data transfer. The processor includes or is executing offload logic 372 (which can be hardware, software, firmware, or a combination). In one example, the offload logic 372 determines where the chunks of compressed data are stored based on a map or algorithm. In one example, the physical location of the chunks of compressed data is defined by one or more of a node number (e.g., sled number), disk number, and a sector range on that disk (e.g., logic block address (LBA) where the chunk is stored). The offload logic 372 then sends the request 373 to the storage device of node 371. The request 373 can include, for example, information identifying the operation to be performed on the compressed data, an address range for the compressed data, and/or other operands necessary for performing the operation. The request 373 can be transmitted as one or more commands, by writing to one or more registers on the storage device or node 371, via assertion of one or more signals to the storage device or node 371, or any other means of communication between the processor or node 370 and the storage device or node 371.

In response to receiving the request to perform the operation, the storage device or node 371 reads the chunk including the associated state information (e.g., CDATA0 and STATE0). CDATA0 and STATE0 are provided to the decompression logic 314. In one example, the decompression logic 314 can include a codec (coder-decoder) decompresses coded compressed data based on the compression algorithm used for compression and the associated state information. Unlike conventional compression and decompression techniques, in the illustrated example the decompression logic 314 is able to decompress a single chunk CDATA0 independently from the other chunks in the compressed data stream. Each compressed token of the compressed data is to span a single chunk, and all information needed to decompress a given chunk is stored with the given chunk. Thus, unlike with conventional compression techniques in which all the chunks of the compressed data stream need to be received prior to decompressing the data stream, each chunk of the compressed data stream can be independently decompressed. Independent decompression of the chunks enables the decompression to be performed where the data is located. For example, where the compressed data is distributed across multiple nodes, each node can independently decompress the chunks at that node. In another example, the storage devices may include circuitry (e.g., compute in memory circuitry) to perform decompression and/or perform operations.

After the decompression logic 314 generates the decompressed data from the compressed data (CDATA0) and state information (STATE0), the decompressed data is sent to processing circuity 315 along with the operation to be performed. The processing circuitry can include a central processing unit (CPU), analog processing circuitry, a field programmable gate array (FPGA), an application specific integrated circuit (ASIC), accelerators, or other processing and/or control circuitry. The processing circuitry can be embedded in the storage device or separate from the storage device. The processing circuitry 315 performs the operation on DATA0 to obtain a result. The result 375 can then be provided to the processor or node 370. Providing the result can include, for example, transmitting the result or storing the result at a specified or predetermined location (e.g., a memory location, a register, etc.). Although only a single storage device/node 371 is shown in FIG. 3, the illustrated technique can be carried out on multiple storage devices or nodes where the compressed data chunks are stored. The operation can thus be offloaded to the storage devices/nodes at the same time for concurrent independent decompression of each chunk without transferring the chunks to a central place for decompression. In another example, the operation may only need to be performed on one or some of the chunks of compressed data, in which case the operation can be offloaded to only the devices or nodes storing the chunks of interest. Thus, the solution presented here enables parallel operation of the offload, and also allows operation of the offload on a selected sub-range of a file/data-stream. These advantages come at the expense of a slight reduction in compression ratio.

Thus, independent decompression of chunks of the compressed data stream where the chunks are located can significantly reduce the amount of data transferred in order to perform an operation on compressed data. Instead of transferring each chunk of compressed data to a central location for decompression, in this example, the only data transferred are the offload requests and the results of the operation.

Note that the example in FIG. 3 assumes that the CDATA0 combined with STATE0 can be read without errors. If an error is encountered, the storage device or node can transfer STATE0 and CDATA0 to the requesting device or node for error correction with parity data stored on another storage device. In one such example, all the compressed data chunks and associated information are transferred to the requesting device or node to perform error correction. At this point, the operation can be performed at the requesting device or node.

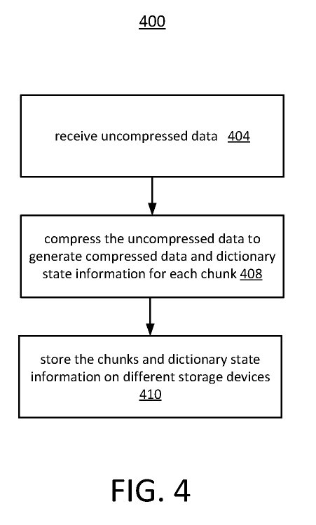

FIG. 4 is a flow chart illustrating an example of a method 400 of compressing and storing data. The method 400 can be performed by processing circuitry, which may include, for example a central processing unit (CPU), analog processing circuitry, a field programmable gate array (FPGA), an application specific integrated circuit (ASIC), accelerators, or other processing and/or control circuitry. In one example, the processing circuitry executes instructions of a program to perform the method 400.

The method begins with some uncompressed data that is to be compressed and stored. The uncompressed data may be, for example, text (e.g., a document with text, email, code, database entries, etc.), a media file (e.g., an image, a video file, a sound file, etc.,), or any other type of data. The uncompressed data is received by the compression logic (e.g., by a software or hardware codec), at operation 404. The compression logic compresses the uncompressed data, at operation 408. The output of the compression algorithm is compressed data, which is divided into multiple portions or chunks and dictionary state information for each chunk. Thus, in one example, each chunk has dictionary state information for that single chunk. The dictionary state information for each chunk includes sufficient information for independent decompression of each chunk. Thus, there is some overlap in the state information amongst chunks of the compressed data stream.

The method then involves storing the chunks and dictionary state information on different storage devices, at operation 410. Each chunk and its associated state information can be stored on a different storage device in the same node, or across multiple nodes. After compressing and storing the data according to this technique, an operation on the compressed data can then be offloaded to the nodes or devices storing the chunks. For example, a processor can send a request to offload an operation to each node or each device storing a chunk of a given compressed data stream.

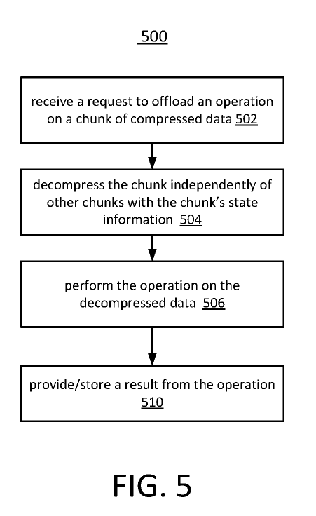

FIG. 5 is flow chart of an example of a method 500 of handling an offload request on compressed data. Some or all of the operations of method 500 can be performed by, for example, processing circuitry on a node where a chunk of compressed data is stored. In another example, some or all of the operations of method 500 can be performed by processing circuitry of a storage device that includes embedded processing circuitry.

The method 500 starts with receiving a request to offload an operation on a chunk of compressed data, at operation 502. Examples of operations include: search operations, replacement, data transformation such as encryption, other stream based offloads, etc. The compressed data is then read from the storage device and decompressed with decompression logic, at operation 504. Decompressing the chunk is achieved with the state information stored with the chunk, and without any of the other chunks of the compressed data stream. After decompression, the operation can be performed on the compressed data, at operation 506. After the operation is performed on the data, a result is provided to the requesting device or node, at operation 510. In the event that the data was modified by the operation, the data can be compressed again after the operation and stored on the storage device.

FIG. 6 illustrates an example of a disaggregated rack architecture in which compression and offload techniques may be implemented. FIG. 6 illustrates an example of a system with K racks 602-1-602-K of computing resources, which may be used in a data center to store and process data. The racks 602-1-602-K can be in a same physical area, or in physically or geographically separate areas. In the illustrated example, each rack includes N compute nodes and M storage nodes, where N and M can vary in different racks. For example, for rack 602-1, N may be 10, but for rack 602-2, N may be 15. A node is a physical or virtual machine including or having access to one or more computing resources. Independent of whether a node is a physical or virtual machine, a node is a unique fault domain with respect to other nodes. A fault domain is an independent domain with no single point of failure (e.g., there is redundant cooling, power, and/or network paths). A storage node is a physical computer (e.g., server) including non-volatile storage. In the example illustrated in FIG. 6, the storage nodes 606 include solid state drives (SSDs) 616 to store data. The storage nodes 606 also include processing circuitry 620, which may include one or more of: a central processing unit (CPU), analog processing circuitry, a field programmable gate array (FPGA), an application specific integrated circuit (ASIC), accelerators, or other processing and/or control circuitry. A compute node is a physical computer including processors. For example, the compute nodes 604 include CPUs 608. The compute node 604 also includes storage 610, which can be a solid-state drive or other non-volatile storage. A compute node can be referred to as a compute sled, blade, shelf, chassis, server, appliance, machine, or computer. Similarly, a storage node can also be referred to as a storage sled, blade, shelf, chassis, server, appliance, machine, or computer.

The compute node illustrated in FIG. 6 includes CPUs 608, storage 610, input/output (I/O) interface logic 615 and logic 614. The I/O interface logic 615 can include hardware and/or software to enable communication both within the compute node and with other nodes. The logic 614 can include hardware, software, or both to implement the compression, decompression, and offloading techniques described in this disclosure. The storage node 606 includes SSDs 616, processing circuitry 620, I/O interface logic 625, and logic 624. The logic 624 can include hardware, software, or both to implement the compression, decompression, and offloading techniques described in this disclosure. The nodes 604 and 606 can include different or additional resources than what is depicted in FIG. 6.

The nodes are communicatively coupled by one or more networks. For example, the nodes within the rack can be coupled via an Ethernet or proprietary local area network (LAN). The racks 602-1-602-K can include a switching hub (not shown in FIG. 6) to implement such a network. Multiple racks can be communicatively coupled to one another via gateways between each rack's network and another, external network that couples the racks to one another.

The nodes in FIG. 6 are disaggregated in the sense that data center hardware resources (e.g., compute, memory, storage, and network resources) can be packaged and installed individually in a rack. For example, storage resources are installed in the racks 602 as storage nodes or sleds, and compute resources are installed in the racks 602 as compute nodes or sleds. Thus, the compute nodes and storage nodes in FIG. 6 differ from conventional servers in that different nodes can include a different balance of computing resources and do not necessarily include all the components of a conventional server. In a conventional rack infrastructure, the computing resources have the granularity of an entire server computer. Thus, in a traditional infrastructure, a deficiency in resources can only be addressed by adding an entire server computer. As an example, to address a deficiency in CPU processing power, one or more additional servers would be added to the rack, which would increase the CPU processing power. However, the additional servers would also increase the storage resources and other power consuming elements, which may be unnecessary and even undesirable. Unlike conventional rack architecture, a disaggregated architecture enables addressing deficiencies in resources by adding more of the specific resources that are lacking without adding additional and unnecessary resources.

Data stored in a datacenter is typically stored across multiple devices, nodes, and or racks to improve load balancing. As discussed above, data may also be compressed to reduce the resources needed to store and transmit the data. Compression of data may be lossless or lossy. An example of lossless compression involves identifying redundancies in data and encoding the data to eliminate or reduce the redundancy. Additional redundancies can be added to the compressed data to improve availability. For example, the chunks can be erasure-coded to generate codes that are stored across multiple nodes.

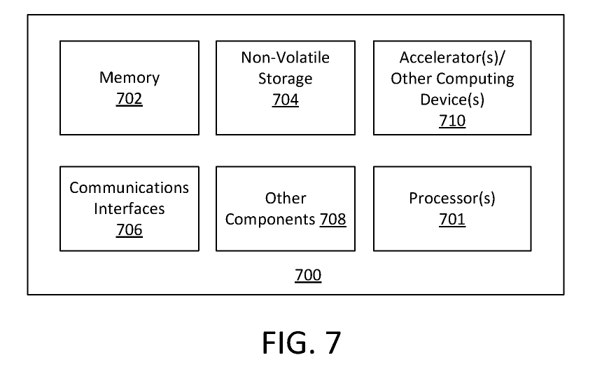

FIG. 7 provides an exemplary depiction of a computing system 700 in which compression and offloading techniques can be implemented. The computing system 700 can be, for example, user equipment, a computer, a personal computer (PC), a desktop computer, a laptop computer, a notebook computer, a netbook computer, a tablet, a smart phone, embedded electronics, a gaming console, a server array or server farm, a web server, a network server, an Internet server, a work station, a mini-computer, a main frame computer, a supercomputer, a network appliance, a web appliance, a distributed computing system, multiprocessor systems, processor-based systems, or combination thereof. As observed in FIG. 7, the system 700 includes one or more processors or processing units 701 (e.g., host processor(s)). The processor(s) 701 may include one or more central processing units (CPUs), each of which may include, e.g., a plurality of general-purpose processing cores. The processor(s) 701 may also or alternatively include one or more graphics processing units (GPUs) or other processing units. The processor(s) 701 may include memory management logic (e.g., a memory controller) and I/O control logic. The processor(s) 701 typically include cache on a same package or near the processor.

The system 700 also includes memory 702 (e.g., system memory). The system memory can be in the same package (e.g., same SoC) or separate from the processor(s) 701. The system 700 can include static random-access memory (SRAM), dynamic random-access memory (DRAM), or both. In some examples, memory 702 may include volatile types of memory including, but not limited to, RAM, D-RAM, DDR SDRAM, SRAM, T-RAM or Z-RAM. One example of volatile memory includes DRAM, or some variant such as SDRAM. Memory as described herein may be compatible with a number of memory technologies, such as DDR4 (DDR version 4, initial specification published in September 2012 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (LPDDR version 5, currently in discussion by JEDEC), HBM2 (HBM version 2, currently in discussion by JEDEC), and/or others, and technologies based on derivatives or extensions of such specifications. In one example, the memory 702 includes a byte addressable DRAM or a byte addressable non-volatile memory such as a byte-addressable write-in-place three dimensional crosspoint memory device, or other byte addressable write-in-place non-volatile memory devices (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

The system 700 also includes communications interfaces 706 and other components 708. The other components may include, for example, a display (e.g., touchscreen, flat-panel), a power supply (e.g., a battery or/or other power supply), sensors, power management logic, or other components. The communications interfaces 706 may include logic and/or features to support a communication interface. For these examples, communications interface 706 may include one or more input/output (I/O) interfaces that operate according to various communication protocols or standards to communicate over direct or network communication links or channels. Direct communications may occur via use of communication protocols or standards described in one or more industry standards (including progenies and variants). For example, I/O interfaces can be arranged as a Serial Advanced Technology Attachment (SATA) interface to couple elements of a node to a storage device. In another example, I/O interfaces can be arranged as a Serial Attached Small Computer System Interface (SCSI) (or simply SAS), Peripheral Component Interconnect Express (PCIe), or Non-Volatile Memory Express (NVMe) interface a storage device with other elements of a node (e.g., a controller, or other element of a node). Such communication protocols may be utilized to communicate through I/O interfaces as described in industry standards or specifications (including progenies or variants) such as the Peripheral Component Interconnect (PCI) Express Base Specification, revision 3.1, published in November 2014 (“PCI Express specification” or “PCIe specification”) or later revisions, and/or the Non-Volatile Memory Express (NVMe) Specification, revision 1.2, also published in November 2014 (“NVMe specification”) or later revisions. Network communications may occur via use of communication protocols or standards such those described in one or more Ethernet standards promulgated by IEEE. For example, one such Ethernet standard may include IEEE 802.3. Network communication may also occur according to one or more OpenFlow specifications such as the OpenFlow Switch Specification. Other examples of communications interfaces include, for example, a local wired point-to-point link (e.g., USB) interface, a wireless local area network (e.g., WiFi) interface, a wireless point-to-point link (e.g., Bluetooth) interface, a Global Positioning System interface, and/or other interfaces.

The computing system 700 also includes non-volatile storage 704, which may be the mass storage component of the system. Non-volatile types of memory may include byte or block addressable non-volatile memory such as, but not limited to, NAND flash memory (e.g., multi-threshold level NAND), NOR flash memory, single or multi-level phase change memory (PCM), resistive memory, nanowire memory, ferroelectric transistor random access memory (FeTRAM), magnetoresistive random access memory (MRAM) that incorporates memristor technology, spin transfer torque MRAM (STT-MRAM), 3-dimensional (3D) cross-point memory structure that includes chalcogenide phase change material (e.g., chalcogenide glass) hereinafter referred to as “3D cross-point memory”, or a combination of any of the above. For these examples, storage 704 may be arranged or configured as a solid-state drive (SSD). The data may be read and written in blocks and a mapping or location information for the blocks may be kept in memory 702. The storage or memory of the system 700 can include processing circuitry, enabling some operations described above to be performed in compute-in-memory. In one example, the non-volatile storage 704 stores the chunks and associated state information discussed above.

The computing system 700 may also include one or more accelerators or other computing devices 710. For example, the computing system 700 may include an Artificial Intelligence (AI) or machine learning accelerator optimized for performing operations for machine learning algorithms, a graphics accelerator (e.g., GPU), or other type of accelerator. An accelerator can include processing circuitry (analog, digital, or both) and may also include memory within the same package as the accelerator 710.

Examples of techniques for compression, decompression, and compute offloading follow.

In one example, a storage node includes input/output (I/O) interface logic to receive a request to perform an operation to access compressed data, a chunk of the compressed data and its associated state information to be stored on the storage node, and logic (e.g., hardware, software, firmware, or a combination) to decompress the chunk at the storage node with its associated state information independently from other chunks of the compressed data, perform the operation on the decompressed data, and provide a result from the operation. In one example, each compressed token of the compressed data is to span a single chunk. In one example, the state information includes dictionary state information for a single chunk. In one example, a portion of the state information for one chunk is replicated in the state information for another chunk. In one example, in response to an error in the chunk, the I/O interface logic transfers the chunk to a requesting device for error correction with parity data stored on another storage node. In one example, the storage node is a storage sled and the request is from a compute sled. In another example, the storage node is or includes a storage device, and the request is from a computing device on a same node as the storage device.

In one example, a compute node includes processing circuitry to compress the uncompressed data to generate compressed data, divide the compressed data into chunks, and generate state information for each chunk of the compressed data, each chunk independently de-compressible with its associated state information. The compute node includes input/output (I/O) interface logic to store the compressed data on a plurality of storage devices, each chunk of the compressed data to be stored on a same storage device as its associated state information. In one example, the I/O interface logic is to send, to one or more of the plurality of storage devices, a request to perform an operation on the compressed data, each chunk to be independently decompressed and the operation to be independently performed on each decompressed chunk, and receive results of the operation from the one or more storage devices. In one example, the processing circuitry is to combine a chunk of compressed data with its associated state information. In one such example, combining a chunk of compressed data with its associated state information involves prepend or appending the associated state information to the chunk of compressed data. In one example, the processing circuitry is to pad one the chunks of compressed data to generate chunks with equal length. In one example, the processing circuitry is to further perform erasure coding on the compressed data together with the associated state information to generate parity data, and store the parity data to non-volatile storage devices other than the plurality of devices storing the chunks of compressed data. In one such example, each of the plurality of storage devices resides on a different storage node. In one example, the plurality of storage devices reside on a same node.

In one example, an article of manufacture comprising a computer readable storage medium having content stored thereon which when accessed causes one or more processors to execute operations to perform a method described herein. In one example, a method involves receiving uncompressed data, compressing the uncompressed data to generate compressed data, dividing the compressed data into chunks, generating state information for each chunk of the compressed data, each chunk independently de-compressible with its associated state information, and storing the compressed data on a plurality of storage devices, each chunk of the compressed data to be stored on a same storage device as its associated state information

In one example, a method involves receiving, at a storage device, a request to perform an operation on a chunk of compressed data, decompressing the chunk of compressed data with its associated state information independently from other chunks of the compressed data, performing the operation on the decompressed data, and providing a result from the operation. In one example, a system includes a plurality of storage devices to store chunks of compressed data, each chunk of the compressed data to be stored on a different storage device, each of the plurality of storage devices including: one or more storage arrays to store a chunk of the compressed data and state information for the chunk, an input/output (I/O) interface to receive a request to perform an operation on compressed data, and processing circuitry to: decompress the chunk of the compressed data independent of other chunks of the compressed data with state information for the chunk, perform the operation on the chunk, and provide a result from the operation. In one example, the system includes a processor coupled with the plurality of storage devices, the processor to send the request to each of the plurality of storage devices to perform the operation on the compressed data.

Embodiments of the invention may include various processes as set forth above. The processes may be embodied in machine-executable instructions. The instructions can be used to cause a general-purpose or special-purpose processor to perform certain processes. Alternatively, these processes may be performed by specific/custom hardware components that contain hardwired logic circuitry or programmable logic circuitry (e.g., FPGA, PLD) for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

Flow diagrams as illustrated herein provide examples of sequences of various process actions. The flow diagrams can indicate operations to be executed by a software or firmware routine, as well as physical operations. In one example, a flow diagram can illustrate the state of a finite state machine (FSM), which can be implemented in hardware, software, or a combination. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various examples; thus, not all actions are required in every embodiment. Other process flows are possible.

To the extent various operations or functions are described herein, they can be described or defined as software code, instructions, configuration, data, or a combination. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine-readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters or sending signals, or both, to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Terms used above to describe the orientation and position of features such as ‘top’, ‘bottom’, ‘over’, ‘under’, and other such terms describing position are intended to clarify the relative location of features relative to other features, and do not describe a fixed or absolute position. For example, a wafer that is described as the top wafer that is above or over a bottom wafer could be described as a bottom wafer that is under or below a top wafer. Therefore, the illustrations and examples herein should be construed in an illustrative, and not a restrictive sense. The scope of the invention should be measured solely by reference to the claims that follow.

What is claimed is:

1. An article of manufacture comprising a computer readable storage medium having content stored thereon which when accessed causes processing circuitry to execute operations to perform a method comprising:
receiving, at a storage device, a request to perform an operation on a chunk of compressed data;
decompressing the chunk of compressed data with its associated state information independently from other chunks of the compressed data;
performing the operation on the decompressed data; and
providing a result from the operation.

2. The article of manufacture of claim 1, wherein:
each compressed token of the compressed data is to span a single chunk.

3. The article of manufacture of claim 1, wherein:
the state information includes dictionary state information for a single chunk.

4. The article of manufacture of claim 1, wherein:
a portion of the state information for one chunk is replicated in the state information for another chunk.

5. The article of manufacture of claim 1, the method further comprising:
in response to an error in the chunk, transferring the chunk to the requesting device for error correction with parity data stored on another storage device.

6. The article of manufacture of claim 1, wherein:
the storage device resides on a storage node and the request is from a compute node.

7. The article of manufacture of claim 1, wherein:
the storage device resides on a same node as the requesting device.

8. An article of manufacture comprising a computer readable storage medium having content stored thereon which when accessed causes processing circuitry to execute operations to perform a method comprising:
receiving uncompressed data;
compressing the uncompressed data to generate compressed data;
dividing the compressed data into chunks;
generating state information for each chunk of the compressed data, each chunk independently de-compressible with its associated state information; and
storing the compressed data on a plurality of storage devices, each chunk of the compressed data to be stored on a same storage device as its associated state information.

9. The article of manufacture of claim 8, the method further comprising:
sending, to one or more of the plurality of storage devices, a request to perform an operation on the compressed data, each chunk to be independently decompressed and the operation to be independently performed on each decompressed chunk; and
receiving results of the operation from the one or more storage devices.

10. The article of manufacture of claim 8, wherein:
each compressed token of the compressed data is to span a single chunk.

11. The article of manufacture of claim 8, wherein:
the state information includes dictionary state information for a single chunk.

12. The article of manufacture of claim 8, the method further comprising:
combining a chunk of compressed data with its associated state information.

13. The article of manufacture of claim 12, wherein combining a chunk of compressed data with its associated state information comprises:
prepending the associated state information to the chunk of compressed data.

14. The article of manufacture of claim 8, further comprising:
padding one the chunks of compressed data to generate chunks with equal length.

15. The article of manufacture of claim 8, wherein:
a portion of the state information for one chunk is replicated in the state information for another chunk.

16. The article of manufacture of claim 8, the method further comprising:
performing erasure coding on the compressed data together with the associated state information to generate parity data; and
storing the parity data to non-volatile storage devices other than the plurality of devices storing the chunks of compressed data.

17. The article of manufacture of claim 8, wherein:
each of the plurality of storage devices resides on a different storage node.

18. The article of manufacture of claim 8, wherein:
the plurality of storage devices reside on a same node.

19. A storage node comprising:
input/output (I/O) interface logic to:
receive a request to perform an operation to access compressed data, a chunk of the compressed data and its associated state information to be stored on the storage node; and
logic to:
decompress the chunk at the storage node with its associated state information independently from other chunks of the compressed data,
perform the operation on the decompressed data, and
provide a result from the operation.

20. The storage node of claim 19, wherein:
each compressed token of the compressed data is to span a single chunk.
